(19) United States
(12) Patent Application Publication
(10) Pub. No.: US 2026/0331437 A1
(43) Pub. Date: Oct. 22, 2026

(54) PLASMA PROCESSING METHOD AND PLASMA PROCESSING APPARATUS

(71) Applicant: Tokyo Electron Limited, Tokyo (JP)

(72) Inventors: Tetsuya OHISHI, Hillsboro, OR (US); Mohd Fairuz BIN BUDIMAN, Miyagi (JP)

(73) Assignee: Tokyo Electron Limited, Tokyo (JP)

(21) Appl. No.: 19/703,126

(22) Filed: Jun. 10, 2026

Related U.S. Application Data
(63) Continuation of application No. PCT/JP2024/044638, filed on Dec. 17, 2024.
(60) Provisional application No. 63/612,152, filed on Dec. 19, 2023.

(51) Int. Cl. H01J 37/32

(52) U.S. Cl. CPC H01J 37/32697; H01J 37/32155; H01J 37/3299; H01J 2237/334

(57) ABSTRACT

A plasma processing method including (a) generating a bias DC signal by a voltage pulse generator, the bias DC signal including a sequence of voltage pulses; (b) supplying the bias DC signal from the voltage pulse generator to a substrate support placed in a chamber via a path that electrically connects the substrate support and the voltage pulse generator; (c) measuring a voltage of the voltage pulse; (d) calculating at least one of a rise time and a fall time of the voltage pulse based on the measured voltage of the voltage pulse; and (e) adjusting at least one of a resistance value of a variable resistor electrically connected to the path and an inductance of a variable inductor electrically connected to the path based on at least one of the rise time or the fall time of the voltage pulse and the voltage of the voltage pulse.

### CROSS-REFERENCE TO RELATED APPLICATIONS

In the present application, the entire contents of PCT Application PCT/JP2024/044638 filed on 17 Dec. 2024, and U.S. Patent Application No. 63/612,152 filed on 19 Dec. 2023, are incorporated herein by reference.

### BACKGROUND

JP 2019-36658 A discloses a technique in which a DC voltage of a negative polarity from a DC power source is periodically applied to a lower electrode.

### SUMMARY

In one exemplary embodiment of the present disclosure, there is provided a plasma processing method including: (a) generating a plasma from a processing gas supplied to a chamber with a source RF signal; (b) generating a bias DC signal by a voltage pulse generator, the bias DC signal including a sequence of voltage pulses; (c) supplying the bias DC signal from the voltage pulse generator to a substrate support placed in the chamber via a path that electrically connects the substrate support and the voltage pulse generator; and (d) adjusting at least one of a resistance value of a variable resistor electrically connected to the path and an inductance of a variable inductor electrically connected to the path based on values of a parameter.

### BRIEF DESCRIPTION OF DRAWINGS

FIG. 1 is a diagram illustrating a configuration example of a plasma processing system.

FIG. 2 is a diagram illustrating a configuration example of a capacitively coupled plasma processing apparatus.

FIG. 3 is a circuit block diagram illustrating an example of a configuration of a power source 30.

FIG. 4 is a circuit block diagram illustrating an example of the configuration of the power source 30.

FIG. 5 is a flowchart illustrating an example of a plasma processing method according to one embodiment.

FIG. 6 is a diagram illustrating an example of a waveform of a bias DC signal.

FIG. 7 is a diagram illustrating an example of the waveform of the bias DC signal.

FIG. 8 is a graph illustrating an example of a measurement result of a voltage of the bias DC signal.

FIG. 9 is a diagram illustrating an example of a timing chart of plasma processing.

FIG. 10 is a graph illustrating an example of the measurement result of the voltage of the bias DC signal.

FIG. 11 is a graph illustrating an example of the measurement result of the voltage of the bias DC signal.

### DETAILED DESCRIPTION

Exemplary embodiments of the present disclosure relate to a plasma processing method and a plasma processing apparatus. Hereinafter each embodiment of the present disclosure will be described below.

In one exemplary embodiment, there is provided a plasma processing method for executing plasma processing on a substrate in a plasma processing apparatus including a chamber. The plasma processing is executed based on one or two or more parameters (i.e., at least one parameter), and the plasma processing method includes: (a) generating a plasma from a processing gas supplied to the chamber with a source RF signal; (b) generating a bias DC signal by a voltage pulse generator, the bias DC signal including a sequence of voltage pulses; (c) supplying the bias DC signal from the voltage pulse generator to a substrate support placed in the chamber via a path that electrically connects the substrate support and the voltage pulse generator; and (d) adjusting at least one of a resistance value of a variable resistor electrically connected to the path and an inductance of a variable inductor electrically connected to the path based on values of the one or two or more parameters.

In one exemplary embodiment, the plasma processing method further includes (e) measuring the values of the one or two or more parameters, in which the (d) includes adjusting at least one of the resistance value of the variable resistor and the inductance of the variable inductor based on the measured values of the one or two or more parameters measured in the (e).

In one exemplary embodiment, the one or two or more parameters include a voltage of the voltage pulse, the (e) includes: (e-1) measuring a voltage value of the voltage pulse as the values of the one or two or more parameters, and (e-2) calculating at least one of a rise time and a fall time of the voltage pulse based on the voltage value of the voltage pulse measured in the (e-1), and in the (d), at least one of the resistance value of the variable resistor and the inductance of the variable inductor is adjusted based on at least one of the rise time or the fall time of the voltage pulse and the voltage value of the voltage pulse.

In one exemplary embodiment, in the (e-1), the voltage of the voltage pulse is measured in the path between the variable resistor and the variable inductor and the substrate support.

In one exemplary embodiment, in the (e-2), the rise time or the fall time of the voltage pulse is a time required for an absolute value of the voltage of the voltage pulse to change from a first voltage value to a second voltage value higher than the first voltage value.

In one exemplary embodiment, the (e-1) includes calculating a maximum value of the absolute value of the voltage of the voltage pulse, and in the (e-2), the first voltage value is 10% or more of the maximum value, and the second voltage value is 90% or less of the maximum value.

In one exemplary embodiment, the variable resistor is connected in series to the voltage pulse generator and the substrate support in the path.

In one exemplary embodiment, the variable inductor is connected in series to the voltage pulse generator and the substrate support in the path.

In one exemplary embodiment, the plasma processing method further includes (f) setting the values of the one or two or more parameters, in which the (d) includes adjusting at least one of the resistance value of the variable resistor and the inductance of the variable inductor based on the setting values of the one or two or more parameters set in the (f).

In one exemplary embodiment, the (f) includes: (f-1) setting the value of at least one of the one or two or more parameters to a first value, and (f-2) setting the value of at least one of the one or two or more parameters to a second value different from the first value, the (d) includes: (d-1) adjusting at least one of the resistance value of the variable resistor and the inductance of the variable inductor based on the first value, and (d-2) adjusting at least one of the resistance value of the variable resistor and the inductance of the variable inductor based on the second value, and the one or two or more parameters include at least one selected from the group consisting of a pressure in the chamber, an elapsed time of the plasma processing, a frequency of the source RF signal, power of the source RF signal, and a flow rate of the processing gas.

In one exemplary embodiment, in the (f), the one or two or more parameters include the frequency of the source RF signal, and the (a) includes: (a-1) generating a plasma with a source RF signal having a first frequency based on the first value set in the (f-1), and (a-2) generating a plasma with a source RF signal having a second frequency based on the second value set in the (f-2), the second frequency being lower than the first frequency.

In one exemplary embodiment, in the (d-1), the resistance value of the variable resistor is adjusted to a first resistance value while the (a-1) is executed, and in the (d-2), the resistance value of the variable resistor is adjusted to a second resistance value higher than the first resistance value while the (a-2) is executed.

In one exemplary embodiment, a voltage pulse of the bias DC signal includes multiple inflection points, and a maximum voltage difference between the multiple inflection points while the (a-1) is executed is greater than a maximum voltage difference between the multiple inflection points while the (a-2) is executed.

In one exemplary embodiment, active species included in plasma generated while the (a-1) and the (a-2) are executed are directed toward the substrate by the (c), and a straightness of the active species toward the substrate while the (a-1) is executed is lower than a straightness of the active species toward the substrate while the (a-2) is executed.

In one exemplary embodiment, a product generated from the processing gas is deposited on the substrate while the (a-1) is executed, and at least a part of the product is removed by the plasma generated from the processing gas while the (a-2) is executed.

In one exemplary embodiment, the resistance value is 5Ω to 500Ω.

In one exemplary embodiment, the inductance is 1 μH to 50 μH.

In one exemplary embodiment, there is provided a plasma processing apparatus executing plasma processing on a substrate based on one or two or more parameters, including: a chamber; and a controller. In the plasma processing apparatus, the controller is configured to execute control including: (a) generating a plasma from a processing gas supplied to the chamber with a source RF signal, (b) generating a bias DC signal by a voltage pulse generator, the bias DC signal including a sequence of voltage pulses, (c) supplying the bias DC signal from the voltage pulse generator to a substrate support via a path that electrically connects the substrate support placed in the chamber and the voltage pulse generator, and (d) adjusting at least one of a resistance value of a variable resistor electrically connected to the path and an inductance of a variable inductor electrically connected to the path based on values of the one or two or more parameters.

Each embodiment of the present disclosure will be described in detail below with reference to the drawings. Furthermore, identical or similar elements in each drawing are denoted by the same reference numeral, and redundant explanations are omitted. Unless otherwise specified, positional relationships of up, down, left, right, and the like will be explained based on positional relationships illustrated in the drawings. The dimensional ratios illustrated in the drawings do not represent actual ratios, and actual ratios are not limited to those illustrated.

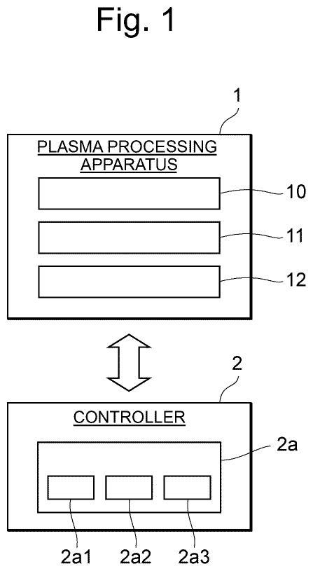

FIG. 1 is a diagram illustrating a configuration example of a plasma processing system. In one embodiment, the plasma processing system includes a plasma processing apparatus 1 and a controller 2. The plasma processing system is one example of a substrate processing system and the plasma processing apparatus 1 is one example of a substrate processing apparatus. The plasma processing apparatus 1 includes a plasma processing chamber 10, a substrate support 11 and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to the gas supply 20, which will be described below, and the gas exhaust port is connected to the exhaust system 40, which will be described below. The substrate support 11 is placed in the plasma processing space and has a substrate support surface for supporting a substrate.

The plasma generator 12 is configured to generate plasma from at least one processing gas supplied into the plasma processing space. Plasma generated in the plasma processing space may be Capacitively Coupled Plasma (CCP), Inductively Coupled Plasma (ICP), Electron-Cyclotron-resonance (ECR) plasma, Helicon Wave Plasma (HWP), Surface Wave Plasma (SWP), or the like. Furthermore, various types of plasma generators, including an Alternating Current (AC) plasma generator and a Direct Current (DC) plasma generator, may be used. In one embodiment, an AC signal (AC power) used in the AC plasma generator has a frequency in the range of 100 kHz to 10 GHz. Accordingly, the AC signal includes a Radio Frequency (RF) signal and a microwave signal. In one embodiment, the RF signal has a frequency in the range of 100 kHz to 150 MHz.

The controller 2 processes computer-executable instructions that cause the plasma processing apparatus 1 to execute various steps described in the present disclosure. The controller 2 may be configured to control each element of the plasma processing apparatus 1 to execute the various steps described herein. In one embodiment, a part or all of the controller 2 may be included in the plasma processing apparatus 1. The controller 2 may include a processor 2a1, a storage 2a2, and a communication interface 2a3. The controller 2 is implemented, for example, by a computer 2a. The processor 2a1 may be configured to read a program from the storage 2a2 and perform various control operations by executing the read program. This program may be stored in the storage 2a2 in advance, or may be acquired via a medium when needed. The acquired program is stored in the storage 2a2 and read from the storage 2a2 and executed by the processor 2a1. The medium may be various storage media readable by the computer 2a, or may be a communication line connected to the communication interface 2a3. The processor 2a1 may be a Central Processing Unit (CPU). The storage 2a2 may include Random Access Memory (RAM), Read Only Memory (ROM), Hard Disk Drive (HDD), Solid State Drive (SSD), or a combination thereof. The communication interface 2a3 may communicate with the plasma processing apparatus 1 via a communication line such as a Local Area Network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

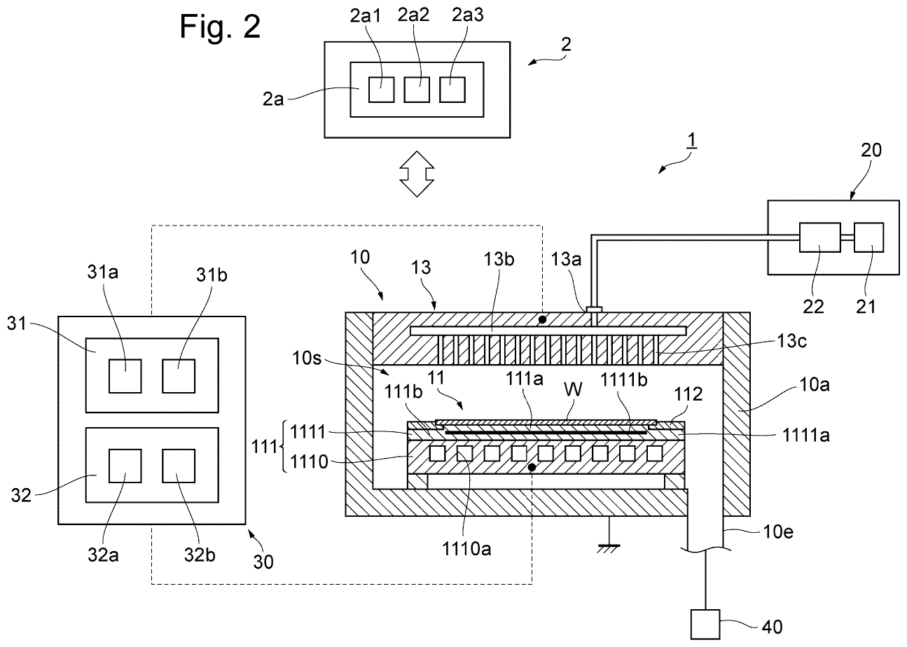

Hereinafter, a configuration example of a capacitively coupled plasma processing apparatus as an example of the plasma processing apparatus 1 will be described. FIG. 2 is a diagram illustrating a configuration example of the capacitively coupled plasma processing apparatus.

The capacitively coupled plasma processing apparatus 1 includes the plasma processing chamber 10, the gas supply 20, a power source 30, and the exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is placed in the plasma processing chamber 10. The shower head 13 is placed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. The wafer is one example of the substrate W. The annular region 111b of the main body 111 surrounds the central region 111a of the main body 111 in a plan view. The substrate W is placed on the central region 111a of the main body 111 and the ring assembly 112 is placed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is placed on the base 1110. The electrostatic chuck 1111 includes a ceramic member 1111a and an electrostatic electrode 1111b placed in the ceramic member 1111a. The ceramic member 1111a has a central region 111a. In one embodiment, the ceramic member 1111a also has an annular region 111b. Other members that surround the electrostatic chuck 1111, such as an annular electrostatic chuck and an annular insulating member, may have the annular region 111b. In this case, the ring assembly 112 may be placed on the annular electrostatic chuck or the annular insulating member, or may be placed on both the electrostatic chuck 1111 and the annular insulating member. Further, at least one RF/DC electrode coupled to an RF power source 31 and/or a DC power source 32 described below may be placed in the ceramic member 1111a. In this case, at least one RF/DC electrode functions as the lower electrode. When the bias RF signal and/or the DC signal described below are supplied to at least one RF/DC electrode, the RF/DC electrode is also called a bias electrode. The conductive member of the base 1110 and at least one RF/DC electrode may function as multiple lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or more heaters are placed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and multiple gas introduction ports 13c. The processing gas supplied to the gas supply port 13a passes through the gas diffusion chamber 13b and is introduced into the plasma processing space 10s from the multiple gas introduction ports 13c. Further, the shower head 13 includes at least one upper electrode. The gas introduction unit may include, in addition to the shower head 13, one or more side gas injectors (SGI) that are attached to one or more openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. As a result, plasma is generated from at least one processing gas supplied into the plasma processing space 10s. Accordingly, the RF power source 31 may function as at least a part of the plasma generator 12. Further, by supplying the bias RF signal to at least one lower electrode, a bias potential is generated in the substrate W, and ion components in the generated plasma can be drawn into the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for generating a plasma. In one embodiment, the source RF signal has a frequency in the range of 10 MHz to 150 MHz. In one embodiment, the first RF generator 31a may be configured to generate multiple source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency in the range of 100 kHz to 60 MHz. In one embodiment, the second RF generator 31b may be configured to generate multiple bias RF signals having different frequencies. The generated one or more bias RF signals are supplied to at least one lower electrode. Further, in various embodiments, at least one of the source RF signal and the bias RF signal may be pulsed.

Further, the power source 30 may include the DC power source 32 coupled to the plasma processing chamber 10. The DC power source 32 includes a first DC generator 32a and a second DC generator 32b. In one embodiment, the first DC generator 32a is configured to be connected to at least one lower electrode to generate a first DC signal. The generated first DC signal is applied to at least one lower electrode. In one embodiment, the second DC generator 32b is configured to be connected to at least one upper electrode to generate a second DC signal. The generated second DC signal is applied to at least one upper electrode.

In various embodiments, the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating the sequence of voltage pulses from the DC signal is connected between the first DC generator 32a and at least one lower electrode. Therefore, the first DC generator 32a and the waveform generator constitute a voltage pulse generator. When the second DC generator 32b and the waveform generator constitute the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e placed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

### Example of Configuration of Power Source 30

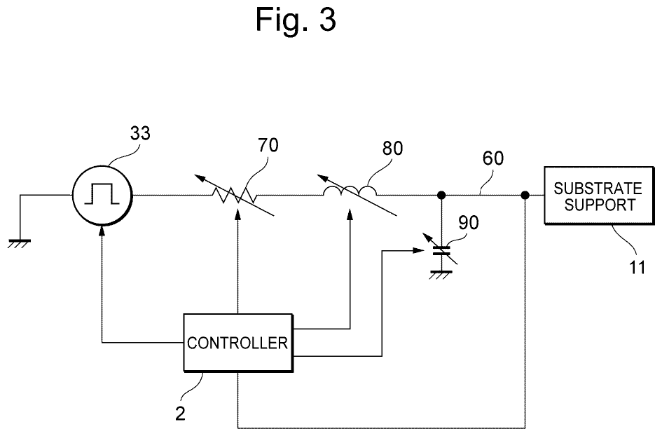

FIG. 3 is a circuit block diagram illustrating an example of a configuration of the power source 30. The power source 30 may be configured to include a voltage pulse generator 33, a path 60, a variable resistor 70, a variable inductor 80, and a variable capacitor 90.

The path 60 is a path for electrically connecting an output of the voltage pulse generator 33 and the substrate support 11. Furthermore, the variable resistor 70 is placed on the path 60 so as to be connected in series to the voltage pulse generator 33 and the substrate support 11. That is, the sequence of voltage pulses generated in the voltage pulse generator 33 is supplied to the substrate support 11 via the path 60 and the variable resistor 70.

The variable resistor 70 is a resistor of which a resistance value can be adjusted. The variable resistor 70 is connected in series to the voltage pulse generator 33 and the substrate support 11 on the path 60. In one embodiment, the variable resistor 70 adjusts the resistance value of the variable resistor 70 based on instructions from the controller 2. The resistance added to the path 60 changes based on the resistance value of the variable resistor 70. The voltage of the voltage pulse output from the voltage pulse generator 33 to the path 60 may decrease based on the resistance value of the variable resistor 70. That is, a maximum value of the voltage of the voltage pulse may be corrected by the variable resistor 70. As a result, a pulse shape of the voltage pulse may be corrected.

The variable inductor 80 is an inductor of which an inductance can be adjusted. The variable inductor 80 is connected in series to the voltage pulse generator 33 and the substrate support 11 on the path 60. The positions on the path 60 where the variable resistor 70 and the variable inductor 80 are placed may be provided as desired. In one embodiment, the variable inductor 80 adjusts an inductance of the variable inductor 80 based on instructions from the controller 2. The inductance added to the path 60 changes based on the inductance of the variable inductor 80. A rise time and a fall time of the voltage pulse output from the voltage pulse generator 33 to the path 60 may be lengthened based on the inductance of the variable inductor 80. That is, the rise time and the fall time of the voltage pulse may be corrected by the variable inductor 80. As a result, the pulse shape of the voltage pulse may be corrected.

The variable capacitor 90 is a capacitor of which a capacitance can be adjusted. The variable capacitor 90 is connected to the path 60 so as to add the capacitance to the path 60. In one embodiment, the variable capacitor 90 adjusts the capacitance of the variable capacitor 90 based on instructions from the controller 2. The capacitance added to the path 60 changes based on the capacitance of the variable capacitor 90. The voltage of the voltage pulse output from the voltage pulse generator 33 to the path 60 may change based on the capacitance of the variable capacitor 90. As an example, the rise time and/or the fall time of the voltage of the voltage pulse may be changed by the variable capacitor 90. As a result, the pulse shape of the voltage pulse may be corrected.

In one embodiment, the controller 2 is electrically connected to the voltage pulse generator 33, the path 60, the variable resistor 70, and the variable inductor 80. The controller 2 may measure the voltage of the voltage pulse propagating along the path 60. The controller 2 may measure the voltage of the voltage pulse in the path 60 between the variable resistor 70 and the variable inductor 80 and the substrate support 11. The controller 2 may control the voltage pulse generator 33, the variable resistor 70, and/or the variable inductor 80 based on the measured voltage of the voltage pulse.

The first RF generator 31a (see FIG. 2) may be electrically connected to the substrate support 11 via the path 60. The first RF generator 31a may be electrically connected to the path 60 between the variable resistor 70 and the variable inductor 80 and the substrate support 11. Furthermore, the first RF generator 31a may be electrically connected to the substrate support 11 via a path different from the path 60.

### Other Examples of Configuration of Power Source 30

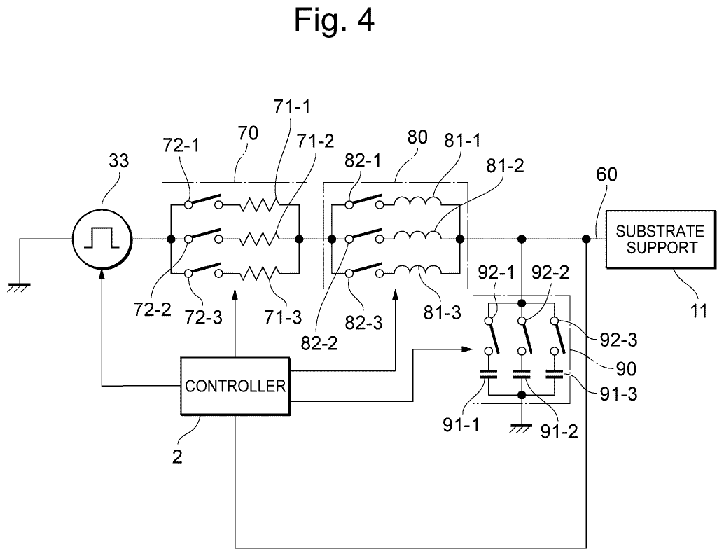

FIG. 4 is a circuit block diagram illustrating another example of the configuration of the power source 30. The variable resistor 70 may be configured to include multiple fixed resistors 71 and multiple switches 72. FIG. 4 illustrates an example including three fixed resistors 71-1 to 71-3 and three switches 72-1 to 72-3. Furthermore, the variable inductor 80 may be configured to include multiple fixed inductors 81 and multiple switches 82. FIG. 4 illustrates an example including three fixed inductors 81-1 to 81-3 and three switches 82-1 to 82-3. The switches 72-1 to 72-3 and the switches 82-1 to 82-3 may be configured to include FET or PIN diodes.

In the example of the variable resistor 70 illustrated in FIG. 4, the fixed resistors 71-1 to 71-3 are connected in parallel to each other. Furthermore, each of the fixed resistors 71-1 to 71-3 has one end and the other end. The switches 72-1 to 72-3 are placed in parallel to each other. Furthermore, each of the switches 72-1 to 72-3 has one end and the other end. One end of each of the switches 72-1 to 72-3 is electrically connected to the voltage pulse generator 33. The other end of each of the switches 72-1 to 72-3 is connected to one end of each of the corresponding fixed resistors 71-1 to 71-3. Furthermore, the other end of each of the fixed resistors 71-1 to 71-3 is electrically connected to the variable inductor 80.

That is, in the variable resistor 70, the switches 72-1 to 72-3 are connected in series to the fixed resistors 71-1 to 71-3. The controller 2 may then control ON/OFF of each of the switches 72-1 to 72-3 to adjust the resistance value of the variable resistor 70. That is, the resistance value of the variable resistor 70 may be adjusted according to the resistance value of the fixed resistor 71 when the corresponding switch 72 is ON. The variable resistor 70 may be configured in such a manner that the multiple fixed resistors 71 are connected in series to each other. In this case, each of the multiple switches 72 may be connected in parallel to the corresponding fixed resistor 71.

In the example of the variable inductor 80 illustrated in FIG. 4, the fixed inductors 81-1 to 81-3 are connected in parallel to each other. Furthermore, each of the fixed inductors 81-1 to 81-3 has one end and the other end. The switches 82-1 to 82-3 are placed in parallel to each other. Furthermore, each of the switches 82-1 to 82-3 has one end and the other end. One end of each of the switches 82-1 to 82-3 is electrically connected to the variable resistor 70. The other end of each of the switches 82-1 to 82-3 is connected to one end of each of the corresponding fixed inductors 81-1 to 81-3. Furthermore, the other end of each of the fixed inductors 81-1 to 81-3 is electrically connected to the substrate support 11.

That is, in the variable inductor 80, the switches 82-1 to 82-3 are connected in series to the fixed inductors 81-1 to 81-3. The controller 2 may then control ON/OFF of each of the switches 82-1 to 82-3 to adjust the inductance of the variable inductor 80. That is, the inductance of the variable inductor 80 may be adjusted according to the inductance of the fixed inductor 81 when the corresponding switch 82 is ON. The variable inductor 80 may be configured in such a manner that the multiple fixed inductors 81 are connected in series to each other. In this case, each of the multiple switches 82 may be connected in parallel to the corresponding fixed inductor 81.

In the example of the variable capacitor 90 illustrated in FIG. 4, the fixed capacitors 91-1 to 91-3 are connected in parallel to each other. Furthermore, each of the fixed capacitors 91-1 to 91-3 has one end and the other end. The switches 92-1 to 92-3 are placed in parallel to each other. Furthermore, each of the switches 92-1 to 92-3 has one end and the other end. One end of each of the switches 92-1 to 92-3 is electrically connected to path 60. The other end of each of the switches 92-1 to 92-3 is connected to one end of each of the corresponding fixed capacitors 91-1 to 91-3. Furthermore, the other end of each of the fixed capacitors 91-1 to 91-3 is grounded.

That is, in the variable capacitor 90, the switches 92-1 to 92-3 are connected in series to the fixed capacitors 91-1 to 91-3. The controller 2 may then control ON/OFF of the switches 92-1 to 92-3 to adjust the capacitance of the variable capacitor 90. That is, the capacitance of the variable capacitor 90 may be adjusted according to the capacitance of the fixed capacitor 91 when the corresponding switch 92 is ON. The variable capacitor 90 may be configured in such a manner that the multiple fixed capacitors 91 are connected in series to each other. In this case, the multiple switches 92 may be connected in parallel to the corresponding fixed capacitor 91, respectively.

### Example of Present Processing Method

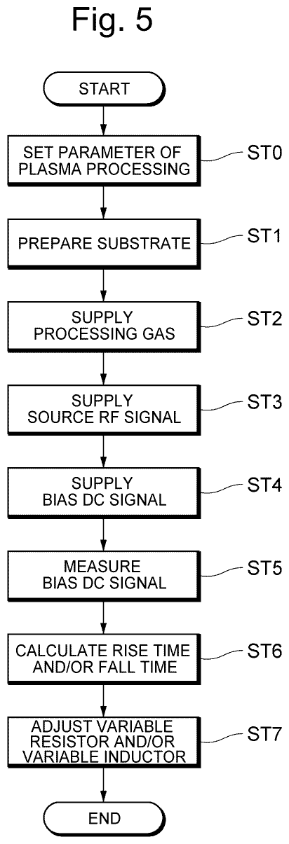

FIG. 5 is a flowchart illustrating an example of a plasma processing method according to one embodiment (hereinafter, the plasma processing method will also be referred to as “the present processing method”). The present processing method includes a step of setting a plasma processing parameter (ST0), a step of preparing a substrate (ST1), a step of supplying a processing gas (ST2), a step of supplying a source RF signal (ST3), a step of supplying a bias DC signal (ST4), a step of measuring a voltage of the bias DC signal (ST5), a step of measuring a rise time and/or a fall time of a voltage pulse (ST6), and a step of adjusting a resistance value of a variable resistor and/or an inductance of a variable inductor (ST7). Hereinafter, an example of the present processing method will be described using an etching processing method for the substrate as an example.

### Step ST0: Setting Parameter of Plasma Processing

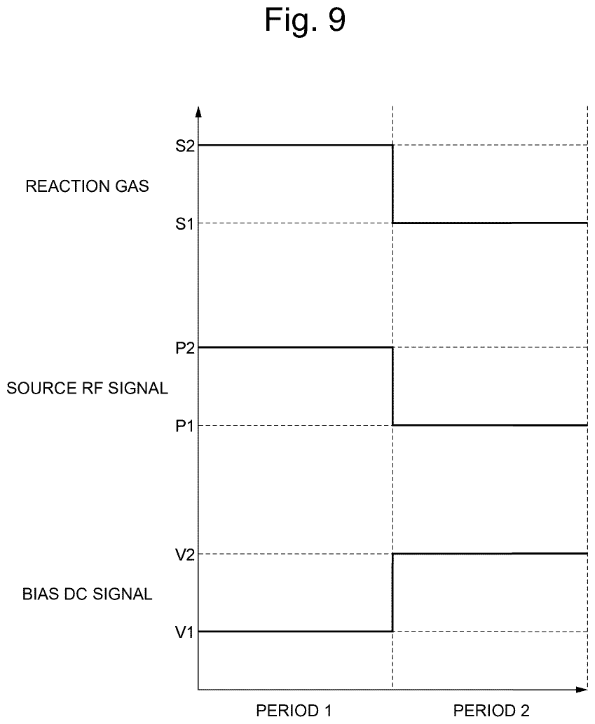

In the step ST0, one or two or more parameters are set for executing plasma processing on the substrate. The step ST2 to the step ST7 described later may be executed based on one or two or more parameters set in the step ST0, respectively. Each of the step ST0 to the step ST7 may be executed by controlling the configuration included in the plasma processing apparatus 1 by the controller 2. As an example, the controller 2 may be configured to include the configuration described in FIG. 9 of U.S. patent application Ser. No. 16/709,430 (U.S. Pat. No. 11,443,954), which is incorporated herein by reference in its entirety.

In one embodiment, setting one or two or more parameters (i.e., at least one parameter) may include storing one or two or more parameters in the storage 2a2 by the controller 2. Furthermore, setting one or two or more parameters may include selecting one or two or more parameters from multiple parameters stored in the storage 2a2 by the controller 2. Furthermore, setting one or two or more parameters may include inputting one or two or more parameters to the plasma processing apparatus 1 via an input apparatus by a user of the plasma processing apparatus 1.

One or two or more parameters may be parameters included in a process recipe for executing the plasma processing. In one embodiment, setting one or two or more parameters may be storing, selecting, or inputting the process recipe.

One or two or more parameters may be parameters for executing the plasma processing on the substrate W. As an example, the parameters may include a frequency of the source RF signal, power of the source RF signal, a frequency of the bias RF signal, power of the bias RF signal, a type of reaction gas included in the processing gas, a flow rate of the processing gas, flow rates of each reaction gas included in the processing gas, a pressure in the chamber, and/or a time of the plasma processing.

Furthermore, one or two or more parameters may include a frequency of the bias DC signal, a duty cycle of the bias DC signal in one cycle, a frequency of the voltage pulse sequence, the voltage of the voltage pulse, the rise time of the voltage pulse, the fall time of the voltage pulse, and/or a voltage difference between inflection points included in the voltage pulse.

Furthermore, when the plasma processing is executed over multiple periods, one or two or more parameters may include the number of periods included in the plasma processing, the order of respective periods, and/or a time of the plasma processing in each period.

### Step ST1: Preparation of Substrate

In the step ST1, the substrate W is prepared. In one embodiment, an etching target film which is a target of the etching processing and a mask film on the etching target film may be provided. In the step ST1, the substrate W may be placed on the substrate support surface on the substrate support 11.

### Step ST2: Supply of Processing Gas

In the step ST2, the processing gas is supplied into the plasma processing chamber 10. The processing gas includes an etching gas that etches the etching target film included in the substrate W. The type and number of the etching gases included in the processing gas may be selected appropriately.

### Step ST3: Supply of Source RF Signal

In the step ST3, the source RF signal is supplied to the substrate support 11 or the shower head 13. The frequency and power of the source RF signal may be selected appropriately. The source RF signal may be a continuous wave or a pulse wave.

### Step ST4: Supply of Bias DC Signal

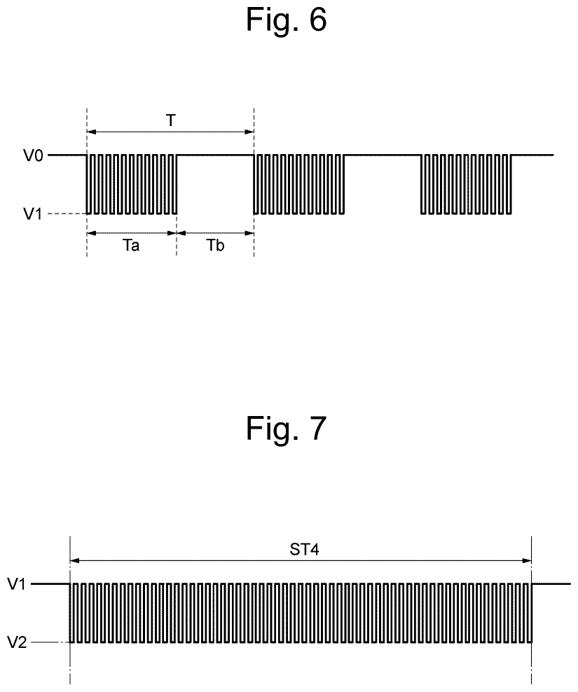

In the step ST4, the bias DC signal is supplied to the substrate support 11. In one embodiment, the bias DC signal is a signal that includes the sequence of voltage pulses. FIG. 6 is a diagram illustrating an example of a waveform of the bias DC signal. The bias DC signal may be a signal that repeats a period T. That is, the period T is one cycle in the bias DC signal. In one embodiment, the period T includes a period Ta and a period Tb. The period Ta may be a period that includes the sequence of voltage pulses. The period Tb is a period that does not include the sequence of voltage pulses. A ratio of the period Ta to the period Tb, that is, the duty cycle, may be set appropriately. The bias DC signal may also be a continuous wave including the voltage pulse during a period in which voltage pulse is supplied to the substrate support 11, as illustrated in FIG. 7.

The voltage of the voltage pulse may be set appropriately according to a target value of a substrate potential. In the bias DC signal, each voltage pulse may be a positive pulse or a negative pulse. In the examples illustrated in FIGS. 6 and 7, each voltage pulse is the negative pulse. That is, the sequence of voltage pulses may repeat a voltage V1 and a voltage V2 which is a lower voltage than the voltage V1. Furthermore, in the period Tb, the voltage of the bias DC signal may be the voltage V1. Here, the voltage V1 may be a minimum setting value for the voltage of the voltage pulse. Furthermore, the voltage V2 may be a maximum setting value for the voltage of the voltage pulse. As an example, the voltage V1 is zero voltage. Further, as an example, the voltage V2 is the negative voltage ranging from −10 kV to −1 kV.

### Step ST5: Measurement of Voltage of Bias DC Signal

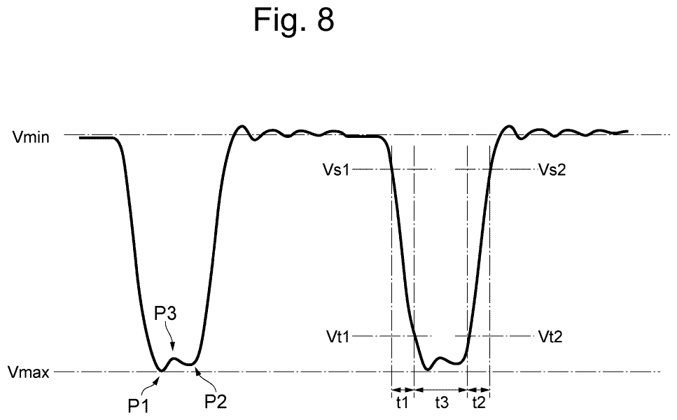

In the step ST5, the controller 2 measures the voltage of the bias DC signal. As the voltage of the bias DC signal, the voltage of the sequence of voltage pulses may be measured in the period Ta. The voltage of the bias DC signal may be measured in the path 60 between the variable resistor 70 and the variable inductor 80 and the substrate support 11. The bias DC signal voltage may be measured in the vicinity of the substrate support 11 in the path 60. FIG. 8 is a graph illustrating an example of a measurement result of the voltage of the bias DC signal. FIG. 8 illustrates a portion of the measurement result of the voltage of the bias DC signal that corresponds to the two voltage pulses in FIGS. 6 and 7. In the step ST5, as illustrated in FIG. 8, the voltage of the bias DC signal may be measured and the voltage waveform of the bias DC signal may be acquired. Furthermore, in the step ST5, the maximum value of the measured voltage of the voltage pulse may be calculated. As an example, the maximum value is a voltage Vmax in FIG. 8. The voltage Vmax may be one of the peak values of the measured values of the voltage pulse. The maximum value may be a maximum value of absolute values of the measured values.

### Step ST6: Calculation of Rise Time and/or Fall Time

In the step ST6, the controller 2 calculates the rise time and/or the fall time of the voltage pulse. In one embodiment, the rise time and/or the fall time of the voltage pulse may be a time required for the voltage of the bias DC signal measured in the step ST5 to reach a second voltage from a first voltage. As an example, the first voltage is a voltage Vs1 and/or a voltage Vs2 in FIG. 8. The voltages Vs1 and Vs2 may be calculated using the following formulae (1-1) and (1-2), respectively.

Vs1=Vmax−Vmin×α1 (1-1)

Vs2=Vmax−Vmin×α2 (1-2)

Here, as an example, α1 and α2 are between 5% and 30%. Furthermore, α1 and α2 may be 10%, 20%, or 30%. α1 and α2 may have values different from each other. Furthermore, the voltages Vs1 and/or Vs2 may be calculated based on the voltage V1 instead of the voltage Vmin.

Furthermore, as an example, the second voltage is a voltage Vt1 and/or a voltage Vt2 in FIG. 8. Absolute values of the voltages Vt1 and Vt2 may be set to be higher than absolute values of the voltages Vs1 and Vs2, respectively. The voltages Vt1 and Vt2 may be calculated using the following formulae (2-1) and (2-2), respectively.

Vt1=Vmax−Vmin×β1 (2-1)

Vt2=Vmax−Vmin×β2 (2-2)

Here, as an example, β1 and β2 are between 70% and 95%. Furthermore, β1 and β2 may be 70%, 80%, or 90%. β1 and β2 may have values different from each other. Furthermore, the voltages Vt1 and Vt2 may be calculated based on the voltage V2 instead of the voltage Vmax.

The controller 2 may calculate the rise time and/or the fall time based on the first voltage and the second voltage. In the example illustrated in FIG. 8, the fall time t1 of the voltage pulse is a time required for the voltage of the voltage pulse to reach the voltage Vt1 from the voltage Vs1. Furthermore, the rise time t2 of the voltage pulse is a time required for the voltage of the voltage pulse to reach the voltage Vs2 from the voltage Vt2. As an example, the controller 2 may calculate the fall time t1 and/or the rise time t2 using the voltage Vmin in FIG. 8 as the first voltage and the voltage Vmax in FIG. 8 as the second voltage.

The controller 2 may calculate a flatness of the waveform of the voltage pulse in the step ST6. The flatness of the waveform of the voltage pulse may be the flatness at a time interval t3. The time interval t3 may be a time interval between the fall time t1 and the rise time t2. The flatness of the waveform of the voltage pulse may be calculated based on a distribution of the voltage values of the voltage pulse. Furthermore, the flatness of the waveform of the voltage pulse may be calculated based on the voltage values of the inflection points included in the waveform of the voltage pulse. As an example, the inflection points may be inflection points P1, P2, and/or P3 in FIG. 8.

### Step ST7: Adjustment of Variable Resistor and/or Variable Inductor

In the step ST7, the controller 2 adjusts the variable resistor 70 and/or the variable inductor 80. In one embodiment, the controller 2 adjusts the variable resistor 70 and/or the variable inductor 80 so that the waveform of the voltage pulse measured in the step ST5 approaches a predetermined shape. The shape may be a shape as desired depending on the purpose of the plasma processing. In one embodiment, the controller 2 may adjust the variable resistor 70 and/or the variable inductor 80 so that the waveform of the voltage pulse approaches a rectangle or a trapezoid. Furthermore, the controller 2 may adjust the variable resistor 70 and/or the variable inductor 80 so that the waveform of the voltage pulse deviates from the rectangle or the trapezoid. Furthermore, the controller 2 may adjust the variable resistor 70 and/or the variable inductor 80 based on setting values and/or measured values of other parameters of the plasma processing.

In one embodiment, the controller 2 may adjust a straightness of active species (i.e., ions/radicals) from plasma toward the substrate W by adjusting the variable resistor 70 and/or the variable inductor 80. As an example, the controller 2 may adjust the variable resistor 70 and/or the variable inductor 80 so that the waveform of the voltage pulse approaches the rectangle or the trapezoid, thereby increasing the straightness of the active species from plasma toward the substrate W. Furthermore, the controller 2 may adjust the variable resistor 70 and/or the variable inductor 80 so that the waveform of the voltage pulse deviates from the rectangle or the trapezoid, thereby reducing the straightness of the active species from plasma toward the substrate W. As used herein, the “straightness” of the active species refers to a directionality/anisotropy of the active species (ion and radial flux) toward the substrate (i.e., wafer), i.e., a degree to which the active species travel along a direction substantially perpendicular to the substrate W. A higher straightness corresponds to a more anisotropic ion flux (more vertical trajectories), while a lower straightness corresponds to a more isotropic ion flux (a broader angular distribution).

As an example, elements that define the proximity of the waveform of the voltage pulse to the shape may include a height of the voltage pulse, a shape of the rise waveform of the voltage pulse, an angle of the rise waveform of the voltage pulse, a shape of the fall waveform of the voltage pulse, an angle of the fall waveform of the voltage pulse, and/or a voltage difference between inflection points included in the waveform of the voltage pulse. The controller 2 may adjust the variable resistor 70 and/or the variable inductor 80 directly or indirectly based on at least one of these elements.

In one embodiment, the controller 2 adjusts the resistance value of the variable resistor 70 based on the voltage Vmax measured or calculated in the step ST5. The controller 2 may compare the voltage Vmax with a predetermined voltage and adjust the resistance value of the variable resistor 70. The predetermined voltage may be the voltage V2. As an example, when the absolute value of the voltage Vmax is higher than the voltage V2, the controller 2 adjusts the variable resistor 70 so that the resistance value of the variable resistor 70 increases. On the other hand, when the absolute value of the voltage Vmax is lower than the voltage V2, the controller 2 adjusts the variable resistor 70 so that the resistance value of the variable resistor 70 decreases. As a result, the voltage Vmax of the voltage pulse output from the voltage pulse generator 33 to the path 60 may be corrected based on the resistance value of the variable resistor 70. The controller 2 may also control the voltage pulse generator 33 to correct the voltage Vmax of the voltage pulse output by the voltage pulse generator 33.

In one embodiment, the controller 2 adjusts the inductance of the variable inductor 80 based on the rise time and/or the fall time calculated in the step ST6. The controller 2 may adjust the inductance of the variable inductor 80 by comparing the rise time and/or the fall time calculated in the step ST6 with a predetermined rise time and/or fall time. As an example, when the fall time t1 calculated in the step ST6 is longer than the predetermined fall time, the controller 2 adjusts the variable inductor 80 so that the inductance of the variable inductor 80 decreases. On the other hand, when the fall time t1 is shorter than the predetermined fall time, the controller 2 adjusts the variable inductor 80 so that the inductance of the variable inductor 80 increases. As a result, the rise time and/or the fall time of the voltage pulse output from the voltage pulse generator 33 to the path 60 may be corrected based on the inductance of the variable inductor 80.

After the resistance value of the variable resistor 70 and/or the inductance of the variable inductor 80 are adjusted in the step ST7, the controller 2 may continue the supply of the source RF signal and the bias DC signal to continue the plasma processing on the substrate W.

### Other Examples of Present Processing Method

The present processing method may be executed by repeatedly executing a cycle that includes two or more periods. In this case, a part or all of the steps ST2 to ST7 may be executed in parallel in each period. The controller 2 may adjust the resistance value of the variable resistor 70 and/or the inductance of the variable inductor 80 so that the voltage pulses have different waveforms in each period. Referring to FIG. 9, an example of the present processing method executed by repeatedly executing the cycle that includes two periods will be described.

FIG. 9 illustrates an example of a timing chart for plasma processing according to one exemplary embodiment. In FIG. 9, a horizontal axis represents the period, and a vertical axis represents a flow rate of a reaction gas included in the processing gas, power of the source RF signal, and the voltage of the bias DC signal. Power of the source RF signal is an effective value of power. Furthermore, the voltage of the bias DC signal is the absolute value of that voltage. In FIG. 9, the vertical axis illustrates larger values as moving upward. The flow rates S1 and S2 in FIG. 9 do not necessarily represent an absolute relationship between the flow rates. Furthermore, the powers P1 and P2 in FIG. 9 do not necessarily represent an absolute relationship between powers. Furthermore, the voltages V1 and V2 in FIG. 9 do not necessarily represent an absolute relationship between the voltages.

In the example illustrated in FIG. 9, one cycle of the present processing method includes a period 1 and a period 2. In each period, the parameter of the plasma processing may be set as desired. In one embodiment, in each period, both a reaction in which deposits are formed on the substrate W by plasma generated from the processing gas (hereinafter, also referred to as the “deposition reaction”) and a reaction in which the deposits are etched (hereinafter also referred to as the “etching reaction”) may occur in parallel. Furthermore, when the deposition reaction exceeds the etching reaction, the deposition of products may proceed on the substrate W. On the other hand, when the etching reaction exceeds the deposition reaction, etching of the products may proceed on the substrate W. Hereinafter, a state in which the deposition reaction exceeds the etching reaction is also referred to as the “deposition reaction is dominant”. Furthermore, a state in which the etching reaction exceeds the deposition reaction is also referred to as the “etching reaction is dominant”.

In the example illustrated in FIG. 9, the plasma processing dominated by the deposition reaction is executed in the period 1. Furthermore, in the period 2, the plasma processing dominated by the etching reaction is executed. Specifically, as an example, the flow rate of the reaction gas may be set to the flow rate S2 in the period 1, while the flow rate may be set to the flow rate S1 lower than flow rate S2 in the period 2. The flow rate S1 may be zero. Furthermore, as an example, the effective value of power of the source RF signal may be set to the power P2 in the period 1, while the effective value may be set to the power P1 lower than the power P2 in the period 2. Furthermore, as an example, the absolute value of the maximum value of the pulse voltage of the bias DC signal may be set to the voltage V1 in period 1, while the absolute value may be set to the voltage V2 higher than the voltage V1 in the period 2. Voltage V1 may be zero voltage. Furthermore, the voltage V2 may be a negative voltage.

In the period 1 and the period 2, the waveforms of the voltage pulses of the bias DC signal may have different shapes, respectively. In one embodiment, the controller 2 may adjust the waveform of the voltage pulse by adjusting the variable resistor 70 and/or the variable inductor 80 in each period. As an example, the controller 2 may adjust the variable resistor 70 and/or the variable inductor 80 according to a balance between the deposition reaction and the etching reaction in each period.

In the example illustrated in FIG. 9, since the deposition reaction is dominant in the period 1, the controller 2 may adjust the variable resistor 70 and/or the variable inductor 80 to reduce the straightness of the active species from plasma toward the substrate W. On the other hand, in the period 2, since the etching reaction is dominant, the controller 2 may adjust the variable resistor 70 and/or the variable inductor 80 to increase the straightness of the active species from plasma toward the substrate W.

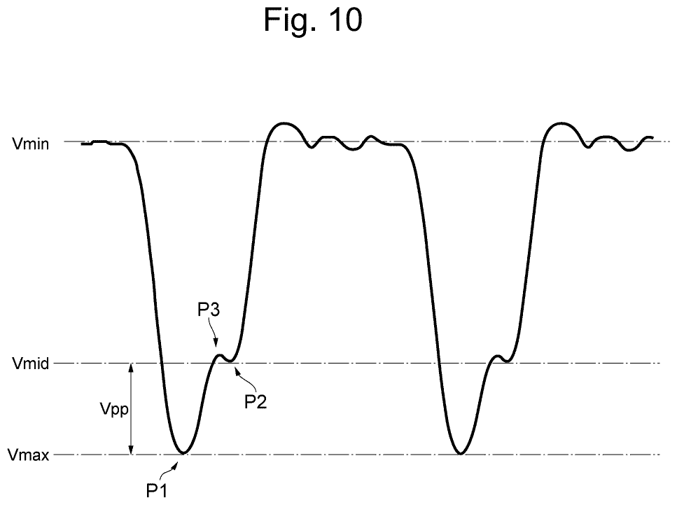

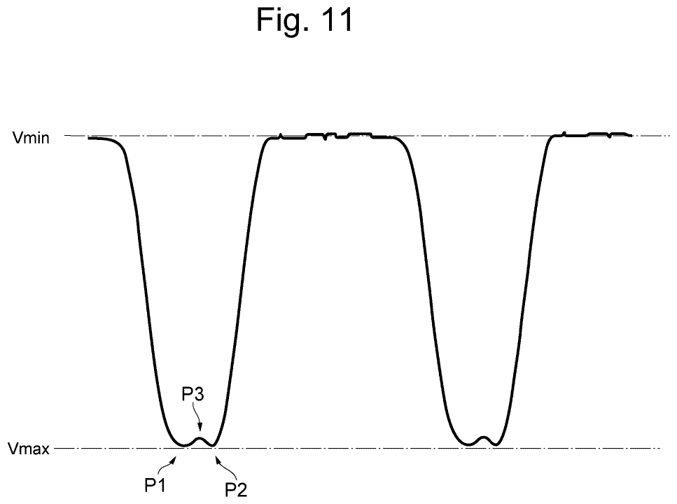

FIGS. 10 and 11 are graphs illustrating an example of the measurement results of the voltage of the bias DC signal. FIG. 10 illustrates the measurement results of the voltage of the bias DC signal in the period 1. FIG. 11 illustrates the measurement results of the voltage of the bias DC signal in the period 2. In FIGS. 10 and 11, the voltage pulse of the bias DC signal has the negative polarity. The waveform of the voltage pulse includes inflection points P1, P2, and P3. The inflection points P1 and P2 are inflection points where a change rate of the voltage of the bias DC signal changes from negative to positive. Furthermore, the inflection point P3 is an inflection point where the change rate of the voltage of the bias DC signal changes from positive to negative. The inflection point P1 may be an inflection point immediately following the fall of the waveform of the voltage pulse. Furthermore, the inflection point P2 may be an inflection point immediately before the rise of the waveform of the voltage pulse.

As illustrated in FIG. 10, the controller 2 may adjust the variable resistor 70 and/or the variable inductor 80 so that a voltage difference Vpp between the voltage value Vmax at the inflection point P1 and the voltage value Vmid at the inflection point P2 is greater than or equal to a predetermined value. As an example, in the period 1, the controller 2 may adjust the variable resistor 70 and/or the variable inductor 80 so that the voltage difference Vpp is equal to or greater than a predetermined value. As a result, the straightness of the active species from plasma towards the substrate W may decrease. For example, in the example illustrated in FIG. 10, the resistance value of the variable resistor 70 is set to 33Ω, and the inductance of the variable inductor 80 is set to 7.5 μH. Furthermore, the voltage difference Vpp may be a potential difference between the inflection point P1 and the inflection point P3.

On the other hand, as illustrated in FIG. 11, the controller 2 may adjust the variable resistor 70 and/or the variable inductor 80 so that the potential difference Vpp is less than or equal to a predetermined value. As an example, in the period 2, the controller 2 may adjust the variable resistor 70 and/or the variable inductor 80 so that the voltage difference Vpp is less than or equal to the predetermined value. As a result, the straightness of the active species from plasma towards the substrate W may increase. The controller 2 may also adjust the variable resistor 70 and/or the variable inductor 80 so that the voltage difference Vpp approaches zero. Furthermore, as an example, in the example illustrated in FIG. 11, the resistance value of the variable resistor 70 is set to 80Ω, and the inductance of the variable inductor 80 is set to 12.5 μH. The voltage difference Vpp may also be a potential difference between the inflection point P1 and the inflection point P3.

According to one embodiment of the present disclosure, the shape of the voltage pulse included in the bias DC signal may be corrected based on the parameter of the plasma processing. For example, the correction may be correction executed during the plasma processing. As a result, even when the setting value of the parameter of the plasma processing affects the waveform of the voltage pulse, this effect can be corrected. Furthermore, even when the setting value of the parameter of the plasma processing is changed during plasma processing, the effect of such a change in the waveform of the voltage pulse can be corrected. As a result, the influence of the setting value of the parameter of the plasma processing and the change thereof on the potential of the substrate W, and thus on etching characteristics, can be suppressed.

Furthermore, according to one embodiment of the present disclosure, it is possible to correct the influence of the change over time on the waveform of the voltage pulse. For example, even when the shape of the voltage pulse supplied to the substrate support 11 changes over time due to repeated etching processing in the plasma processing apparatus 1, this change over time in the voltage pulse can be corrected. As a result, since the change over time in the potential of the substrate W can be suppressed, the change over time in etching characteristics caused by the change over time in the voltage pulse can be suppressed.

Furthermore, according to one embodiment of the present disclosure, the change in the waveform of the voltage pulse generated during the plasma processing can be corrected during the plasma processing. As a result, since the change in the potential of the substrate W that occurs during the plasma processing can be suppressed, the change in the etching characteristics caused by the change in the voltage pulse generated during the plasma processing can be suppressed.

Furthermore, according to one embodiment of the present disclosure, the waveform of the voltage pulse can be corrected at any timing during the plasma processing. For example, in the plasma processing, when a cycle including two or more periods is repeatedly executed, the waveform of the voltage pulse may be corrected for each period. As a result, the waveform of the voltage pulse can be corrected according to the purpose of the plasma processing in each period.

According to one exemplary embodiment of the present disclosure, a technique capable of correcting the voltage pulse of the bias DC signal can be provided.

The present disclosure may include, for example, the following configurations.

### Aspect 1

A plasma processing method for executing plasma processing on a substrate in a plasma processing apparatus including a chamber, in which the plasma processing is executed based on one or two or more parameters, the plasma processing method including:
(a) generating a plasma from a processing gas supplied to the chamber with a source RF signal;
(b) generating a bias DC signal by a voltage pulse generator, the bias DC signal including a sequence of voltage pulses;
(c) supplying the bias DC signal from the voltage pulse generator to a substrate support placed in the chamber via a path that electrically connects the substrate support and the voltage pulse generator; and
(d) adjusting at least one of a resistance value of a variable resistor electrically connected to the path and an inductance of a variable inductor electrically connected to the path based on values of the one or two or more parameters.

### Aspect 2

The plasma processing method according to Aspect 1, further including:
(e) measuring the values of the one or two or more parameters,
in which the (d) includes adjusting at least one of the resistance value of the variable resistor and the inductance of the variable inductor based on the measured values of the one or two or more parameters measured in the (e).

### Aspect 3

The plasma processing method according to Aspect 2, in which the one or two or more parameters include a voltage of the voltage pulse,
the (e) includes:
(e-1) measuring a voltage value of the voltage pulse as the values of the one or two or more parameters, and
(e-2) calculating at least one of a rise time and a fall time of the voltage pulse based on the voltage value of the voltage pulse measured in the (e-1), and
in the (d), at least one of the resistance value of the variable resistor and the inductance of the variable inductor is adjusted based on at least one of the rise time or the fall time of the voltage pulse and the voltage value of the voltage pulse.

### Aspect 4

The plasma processing method according to Aspect 3, in which in the (e-1), the voltage of the voltage pulse is measured in the path between the variable resistor and the variable inductor and the substrate support.

### Aspect 5

The plasma processing method according to Aspect 3 or 4, in which in the (e-2), the rise time or the fall time of the voltage pulse is a time required for an absolute value of the voltage of the voltage pulse to change from a first voltage value to a second voltage value higher than the first voltage value.

### Aspect 6

The plasma processing method according to Aspect 5, in which the (e-1) includes calculating a maximum value of the absolute value of the voltage of the voltage pulse, and
in the (e-2), the first voltage value is 10% or more of the maximum value, and the second voltage value is 90% or less of the maximum value.

### Aspect 7

The plasma processing method according to any one of Aspects 3 to 6, in which the variable resistor is connected in series to the voltage pulse generator and the substrate support in the path.

### Aspect 8

The plasma processing method according to any one of Aspects 3 to 7, in which the variable inductor is connected in series to the voltage pulse generator and the substrate support in the path.

### Aspect 9

The plasma processing method according to any one of Aspects 1 to 8, further including:
(f) setting the values of the one or two or more parameters,
in which the (d) includes adjusting at least one of the resistance value of the variable resistor and the inductance of the variable inductor based on the setting values of the one or two or more parameters set in the (f).

### Aspect 10

The plasma processing method according to Aspect 9, in which the (f) includes:
(f-1) setting the value of at least one of the one or two or more parameters to a first value, and
(f-2) setting the value of at least one of the one or two or more parameters to a second value different from the first value,
the (d) includes:
(d-1) adjusting at least one of the resistance value of the variable resistor and the inductance of the variable inductor based on the first value, and
(d-2) adjusting at least one of the resistance value of the variable resistor and the inductance of the variable inductor based on the second value, and
the one or two or more parameters include at least one selected from the group consisting of a pressure in the chamber, an elapsed time of the plasma processing, a frequency of the source RF signal, power of the source RF signal, and a flow rate of the processing gas.

### Aspect 11

The plasma processing method according to Aspect 10, in which in the (f), the one or two or more parameters include the frequency of the source RF signal, and
the (a) includes:
(a-1) generating a plasma with a source RF signal having a first frequency based on the first value set in the (f-1), and
(a-2) generating a plasma with a source RF signal having a second frequency based on the second value set in the (f-2), the second frequency being lower than the first frequency.

### Aspect 12

The plasma processing method according to Aspect 11, in which in the (d-1), the resistance value of the variable resistor is adjusted to a first resistance value while the (a-1) is executed, and
in the (d-2), the resistance value of the variable resistor is adjusted to a second resistance value higher than the first resistance value while the (a-2) is executed.

### Aspect 13

The plasma processing method according to Aspect 12, in which a voltage pulse of the bias DC signal includes multiple inflection points, and
a maximum voltage difference between the multiple inflection points while the (a-1) is executed is greater than a maximum voltage difference between the multiple inflection points while the (a-2) is executed.

### Aspect 14

The plasma processing method according to Aspect 12, in which active species included in plasma generated while the (a-1) and the (a-2) are executed are directed toward the substrate by the (c), and
a straightness of the active species toward the substrate while the (a-1) is executed is lower than a straightness of the active species toward the substrate while the (a-2) is executed.

### Aspect 15

The plasma processing method according to Aspect 12, in which a product generated from the processing gas is deposited on the substrate while the (a-1) is executed, and
at least a part of the product is removed by the plasma generated from the processing gas while the (a-2) is executed.

### Aspect 16

The plasma processing method according to any one of Aspects 1 to 15, in which the resistance value is 5Ω to 500Ω.

### Aspect 17

The plasma processing method according to any one of Aspects 1 to 16, in which the inductance is 1 μH to 50 μH.

### Aspect 18

A plasma processing apparatus executing plasma processing on a substrate based on one or two or more parameters, including:
a chamber; and
a controller,
in which the controller is configured to execute control including:
(a) generating a plasma from a processing gas supplied to the chamber with a source RF signal,
(b) generating a bias DC signal by a voltage pulse generator, the bias DC signal including a sequence of voltage pulses,
(c) supplying the bias DC signal from the voltage pulse generator to a substrate support via a path that electrically connects the substrate support placed in the chamber and the voltage pulse generator, and
(d) adjusting at least one of a resistance value of a variable resistor electrically connected to the path and an inductance of a variable inductor electrically connected to the path based on values of the one or two or more parameters.

The exemplary embodiments described above may be modified in various ways without departing from the scope and spirit of the present disclosure. For example, within the scope of the ordinary creative ability of a person skilled in the art, some components of one embodiment can be added to other embodiments. Furthermore, some components in one embodiment can be replaced with corresponding components in another embodiment.

Reference Signs List

What is claimed is:

1. A plasma processing method for executing plasma processing comprising:
(a) generating a plasma from a processing gas supplied to a chamber with a source RF signal;
(b) generating a bias DC signal by a voltage pulse generator, the bias DC signal including a sequence of voltage pulses;
(c) supplying the bias DC signal from the voltage pulse generator to a substrate support placed in the chamber via a path that electrically connects the substrate support and the voltage pulse generator; and
(d) adjusting at least one of a resistance value of a variable resistor electrically connected to the path and an inductance of a variable inductor electrically connected to the path based on values of a parameter.

2. The plasma processing method according to claim 1, further comprising:
(e) measuring the values of the parameter,
wherein the (d) includes adjusting at least one of the resistance value of the variable resistor and the inductance of the variable inductor based on the measured values of the parameter measured in the (e).

3. The plasma processing method according to claim 2, wherein the parameter include a voltage of the voltage pulse,
the (e) includes:
(e-1) measuring a voltage value of the voltage pulse as the values of the parameter, and
(e-2) calculating at least one of a rise time and a fall time of the voltage pulse based on the voltage value of the voltage pulse measured in the (e-1), and
in the (d), at least one of the resistance value of the variable resistor and the inductance of the variable inductor is adjusted based on at least one of the rise time or the fall time of the voltage pulse and the voltage value of the voltage pulse.

4. The plasma processing method according to claim 3, wherein in the (e-1), the voltage of the voltage pulse is measured in the path between the variable resistor and the variable inductor and the substrate support.

5. The plasma processing method according to claim 3, wherein in the (e-2), the rise time or the fall time of the voltage pulse is a time required for an absolute value of the voltage of the voltage pulse to change from a first voltage value to a second voltage value higher than the first voltage value.

6. The plasma processing method according to claim 5, wherein the (e-1) includes calculating a maximum value of the absolute value of the voltage of the voltage pulse, and
in the (e-2), the first voltage value is 10% or more of the maximum value, and the second voltage value is 90% or less of the maximum value.

7. The plasma processing method according to claim 3, wherein the variable resistor is connected in series to the voltage pulse generator and the substrate support in the path.

8. The plasma processing method according to claim 3, wherein the variable inductor is connected in series to the voltage pulse generator and the substrate support in the path.

9. The plasma processing method according to claim 1, further comprising:
(f) setting the values of the parameter,
wherein the (d) includes adjusting at least one of the resistance value of the variable resistor and the inductance of the variable inductor based on the set values of the parameter set in the (f).

10. The plasma processing method according to claim 9, wherein the (f) includes:
(f-1) setting the value of at least one of the parameter to a first value, and
(f-2) setting the value of at least one of the parameter to a second value different from the first value,
the (d) includes:
(d-1) adjusting at least one of the resistance value of the variable resistor and the inductance of the variable inductor based on the first value, and
(d-2) adjusting at least one of the resistance value of the variable resistor and the inductance of the variable inductor based on the second value, and
the parameter includes at least one selected from the group consisting of a pressure in the chamber, an elapsed time of the plasma processing, a frequency of the source RF signal, power of the source RF signal, and a flow rate of the processing gas.

11. The plasma processing method according to claim 10, wherein in the (f), the parameter include the frequency of the source RF signal, and
the (a) includes:
(a-1) generating a plasma with a source RF signal having a first frequency based on the first value set in the (f-1), and
(a-2) generating a plasma with a source RF signal having a second frequency based on the second value set in the (f-2), the second frequency being lower than the first frequency.

12. The plasma processing method according to claim 11, wherein in the (d-1), the resistance value of the variable resistor is adjusted to a first resistance value while the (a-1) is executed, and
in the (d-2), the resistance value of the variable resistor is adjusted to a second resistance value higher than the first resistance value while the (a-2) is executed.

13. The plasma processing method according to claim 12, wherein a voltage pulse of the bias DC signal includes inflection points, and
a maximum voltage difference between the inflection points while the (a-1) is executed is greater than a maximum voltage difference between the inflection points while the (a-2) is executed.

14. The plasma processing method according to claim 12, wherein active species included in plasma generated while the (a-1) and the (a-2) are executed are directed toward the substrate by the (c), and
a straightness of the active species toward the substrate while the (a-1) is executed is lower than a straightness of the active species toward the substrate while the (a-2) is executed.

15. The plasma processing method according to claim 12, wherein a product generated from the processing gas is deposited on the substrate while the (a-1) is executed, and
at least a part of the product is removed by the plasma generated from the processing gas while the (a-2) is executed.

16. The plasma processing method according to claim 1, wherein the resistance value is 5Ω to 500Ω.

17. The plasma processing method according to claim 1, wherein the inductance is 1 μH to 50 μH.

18. A plasma processing apparatus executing plasma processing on a substrate based on parameter, comprising:
a chamber;
a substrate support disposed in the chamber, the substrate support being configured to support a substrate;
a source RF generator electrically coupled to at least one of the substrate support and an upper electrode of the chamber;
a voltage pulse generator;
a path that electrically connects the voltage pulse generator and the substrate support;
a variable resistor electrically connected to the path;
a variable inductor electrically connected to the path; and
controller circuitry communicatively coupled to the source RF generator, the voltage pulse generator, the variable resistor, and the variable inductor, the controller circuitry being configured to:
(a) control the source RF generator to supply a source RF signal that generates a plasma from the processing gas when the processing gas is supplied to the chamber;
(b) control the voltage pulse generator to generate a bias DC signal that includes a sequence of voltage pulses;
(c) cause the bias DC signal to be supplied from the voltage pulse generator to the substrate support via the path; and
(d) adjust at least one of a resistance value of the variable resistor and an inductance of the variable inductor based on a value of a parameter associated with the plasma processing apparatus.

19. A plasma processing apparatus, comprising:
a chamber configured to receive a processing gas;
a substrate support disposed in the chamber, the substrate support being configured to support a substrate;
a source RF generator;
a voltage pulse generator;
a path that electrically connects the voltage pulse generator and the substrate support;
a variable resistor electrically connected to the path; and
controller circuitry communicatively coupled to the source RF generator, the voltage pulse generator, and the variable resistor, the controller circuitry being configured to:
(a) control the source RF generator to supply, during a first time period, a source RF signal having a first frequency, and to supply, during a second time period, a source RF signal having a second frequency lower than the first frequency;
(b) control the voltage pulse generator to generate a bias DC signal that includes a sequence of voltage pulses, each voltage pulse including a plurality of inflection points;
(c) cause the bias DC signal to be supplied from the voltage pulse generator to the substrate support via the path; and
(d) adjust a resistance value of the variable resistor such that the resistance value during the first time period is lower than the resistance value during the second time period, and such that a maximum voltage difference between the plurality of inflection points during the first time period is greater than a maximum voltage difference between the plurality of inflection points during the second time period.

20. The plasma processing apparatus of claim 19, further comprising a variable capacitor electrically connected to the path, wherein the controller circuitry is further configured to adjust a capacitance of the variable capacitor.
